(19) United States
(12) Patent Application Publication
(10) Pub. No.: US 2025/0141192 A1
(43) Pub. Date: May 1, 2025

(54) VCSEL ARRAY

(71) Applicant: SHENZHEN RAYSEES AI TECHNOLOGY CO., LTD., Shenzhen (CN)

(72) Inventors: Jianyang Zhao; Siva Kumar Lanka, Reno, NV (US); Yongxiang He, Sunnyvale, CA (US); Yang Wang, Hefei (CN)

(73) Assignee: SHENZHEN RAYSEES AI TECHNOLOGY CO., LTD., Shenzhen (CN)

(21) Appl. No.: 18/037,266

(22) PCT Filed: Mar. 16, 2023
(86) PCT No.: PCT/CN2023/081923

§ 371 Date: May 16, 2023

(51) Int. Cl. H01S 5/42; H01S 5/16; H01S 5/183

(52) U.S. Cl. CPC H01S 5/423; H01S 5/16; H01S 5/18311; H01S 5/18394

(57) ABSTRACT

A VCSEL array includes adjacent first and second VCSEL elements and a trench surrounding the VCSEL arrays. The first and second VCSEL elements include a first output window and a second output window. The first VCSEL element includes a part of a metal layer shared by the first and second VCSEL elements. The distance between the inner edge of the trench and the center of the first output window is larger than half the distance between centers of the first and second output windows.

### FIELD OF INVENTION

This invention generally relates to Vertical Cavity Surface Emitting Lasers (VCSELs) and specifically to VCSEL arrays.

### BACKGROUND OF THE INVENTION

Compared to edge-emitting semiconductor lasers with a horizontal Fabry-Perot resonator and cleaved facets acting as mirrors, VCSELs have a vertical cavity and emit a circular beam normal to the surface. VCSELs have many advantages over edge-emitting semiconductor lasers such as compact size, small beam spot, wavelength stability, spectral width, fast rise time, ease of fabricating two-dimensional (2-D) VCSEL array, etc.

VCSELs and VCSEL arrays have become an indispensible part in many areas. VCSEL arrays can provide much higher output power than a single VCSEL emitter. VCSEL arrays also provide a light source for structured light applications. When a VCSEL array is denser, its power can be increased, enabling a longer sensing range or deeper detection depth. In addition, a denser VCSEL array offers more pixels and thus higher sensing resolution. It is desirable to lower the cost of VCSEL arrays of reduced pitch and higher density.

### SUMMARY OF THE INVENTION

The present invention discloses methods and apparatus for VCSEL arrays. In one aspect, a VCSEL array includes a substrate, VCSEL elements over the substrate, and a trench surrounding the VCSEL elements. The VCSEL elements include a first element and a second element that are adjacent. The first element includes a first reflector region over the substrate, a second reflector region over the first reflector region, an active region between the first reflector region and second reflector region, a part of a metal layer shared by the first and second elements, and a first output window. The distance between the inner edge of the trench and the center of the first output window is larger than fifty percent of the distance between the center of the first output window and the center of a second output window of the second element and smaller than the distance between the center of the first output window and the center of the second output window.

In another aspect, a method for fabricating a VCSEL array includes forming VCSEL elements including a first element and a second element over a substrate, forming a metal layer including a part shared by the first and second elements, forming a trench surrounding the VCSEL elements, forming holes around each of the VCSEL elements, and forming a first oxide aperture and a second oxide aperture of the first and second elements respectively. The first and second elements are adjacent. The distance between the inner edge of the trench and the center of the first oxide aperture is larger than fifty percent of the distance between the center of the first oxide aperture and the center of the second oxide aperture and smaller than the distance between the center of the first oxide aperture and the center of the second oxide aperture.

In another aspect, a VCSEL array includes a substrate, VCSEL elements over the substrate, and a trench surrounding the VCSEL elements. The VCSEL elements include a first element and a second element that are adjacent. The first element includes a first reflector region over the substrate, a second reflector region over the first reflector region, an active region between the first reflector region and second reflector region, and a first oxide aperture between the first reflector region and second reflector region. The distance between the inner edge of the trench and the center of the first oxide aperture is larger than fifty percent of the distance between the center of the first oxide aperture and the center of a second oxide aperture of the second element and smaller than the distance between the center of the first oxide aperture and the center of the second oxide aperture.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings.

FIG. 1 schematically illustrates a cross-sectional view of a VCSEL array at a certain stage during a fabrication process, according to embodiments of the present invention.

FIGS. 2 and 3 schematically illustrate a cross-sectional view and a top view of the VCSEL array shown in FIG. 1 after a metal layer is deposited, according to embodiments of the present invention.

FIGS. 4 and 5 schematically illustrate a top view and a cross-sectional of the VCSEL array shown in FIGS. 2 and 3 after a trench and holes are formed, according to embodiments of the present invention.

FIG. 6 schematically illustrates a cross-sectional view of the VCSEL array shown in FIGS. 4 and 5 after an oxidation process, according to embodiments of the present invention.

FIGS. 7 and 8 schematically illustrate cross-sectional views of the VCSEL array shown in FIG. 6 at a certain stage during the fabrication process, according to embodiments of the present invention.

FIG. 9 schematically illustrates a top view of the VCSEL array shown in FIGS. 7 and 8, according to embodiments of the present invention.

FIG. 10 is a flow chart illustrating a schematic fabrication process of a VCSEL array, according to embodiments of the present invention.

### DETAILED DESCRIPTION

Detailed description of the present invention is provided below along with figures and embodiments, which further clarifies the objectives, technical solutions, and advantages of the present invention. Wherever possible, the same reference numbers are used throughout the drawings to refer to the same or like parts. It is noted that schematic embodiments discussed herein are merely for illustrating the invention. The present invention is not limited to the embodiments disclosed.

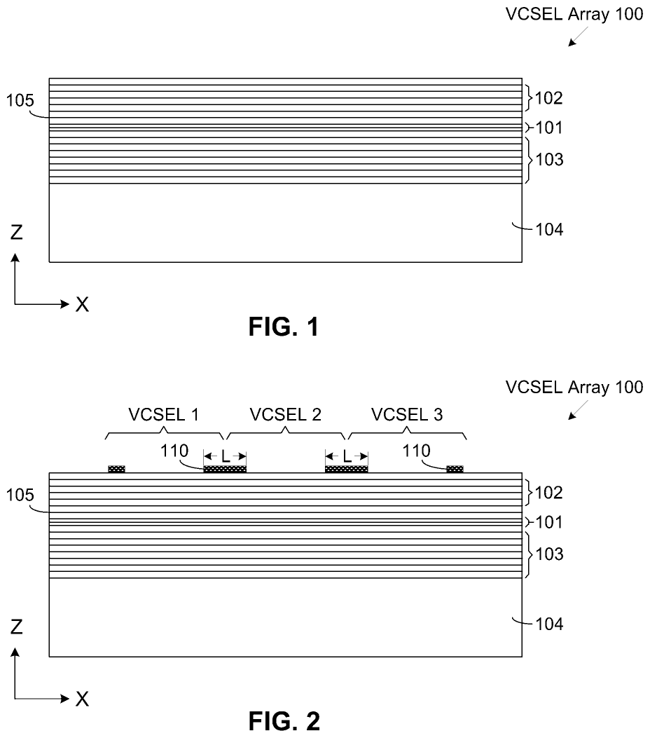

FIG. 1 shows a VCSEL array 100 at a certain fabrication stage in a cross-sectional view according to embodiments of the present invention. Cross-sectional views in FIG. 1 and other figures of the present disclosure are in an X-Z or Y-Z plane. Top views in the present disclosure are in X-Y planes. As shown in FIG. 1, VCSEL array 100 exemplarily includes an active region 101, a top reflector region 102, and a bottom reflector region 103. Bottom reflector region 103, active region 101, and top reflector region 102 are grown over a substrate 104 sequentially. Active region 101 may contain a multiple-quantum-well (MQW) configuration. Top and bottom reflector regions 102 and 103 are electrically conductive. Top reflector region 102 may contain a p-type Distributed Bragg Reflector (DBR), while bottom reflector region 103 may contain an n-type DBR. Substrate 104 may be a conductive n-type semiconductor substrate and include, for example, a Group III-V compound such as gallium arsenide (GaAs), indium phosphide (InP), or III-nitride.

VCSEL array 100 represents a top-emitting VCSEL structure which emits output beams through the top surface when charged with an electrical current. Between top and bottom reflector regions 102 and 103, e.g., between top reflector region 102 and active region 101, a high Al-content layer 105 is formed. Layer 105 has relatively higher aluminum content than other layers and is arranged for forming an oxide layer and oxide apertures. The DBRs, active region, and high Al-content layer may be grown epitaxially over a top surface of substrate 104. The epitaxial growth may be performed by molecular beam epitaxy (MBE) or metal organic chemical vapor deposition (MOCVD).

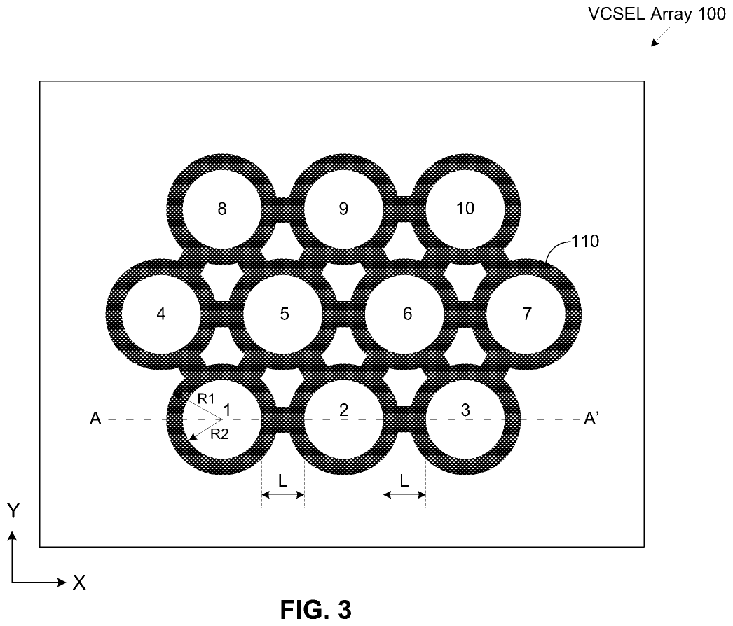

FIGS. 2 and 3 schematically show VCSEL array 100 in a cross-sectional view and a top view at a certain fabrication stage according to embodiments of the present invention. FIG. 2 is taken along a line AA′ of FIG. 3. After top reflector region 102 is made, a metal deposition process is performed to form a metal layer 110. Metal layer 110 is grown over top reflector region 102. For example, a photoresist layer may be deposited on the top surface of VCSEL array 100. A part of the photoresist layer may be exposed and developed. Other parts of the photoresist layer that are not exposed and developed may be removed. Then, metal layer 110 may be deposited in areas where the photoresist layer is removed in a lift-off process. In some aspects, the metal layer may be deposited by chemical vapor deposition (CVD).

Optionally, metal layer 110 has multiple annular shapes or rings in an X-Y plane in some cases. The ring may also be referred to as a metal layer ring. As shown in FIG. 3, VCSEL elements 1-10 are configured exemplarily. Each ring corresponds to a VCSEL element and surrounds an output window of the VCSEL element. The shape, dimension, and arrangement of metal layer 110 as illustrated in FIGS. 2 and 3 are exemplary and for description purposes. Optionally, metal layer 110 may have a pattern other than a ring shape. For example, metal layer 110 may have a pattern that surrounds the output window of each VCSEL element with separate portions (not shown). In descriptions below, metal layer 110 with ring shapes is used exemplarily.

For metal layer 110 with ring shapes, each ring is a p-metal contact that is electrically connected to the top reflector region of a VCSEL element. As shown in FIGS. 2 and 3, two adjacent VCSEL elements may share a part of metal layer 110. Assuming the outer radius and inner radius of the metal layer ring are R1 and R2, and the length of the shared part of metal layer 110 is L along a line passing through centers of adjacent rings. In some cases, the value of L may be equal to or smaller than twice the difference between R1 and R2.

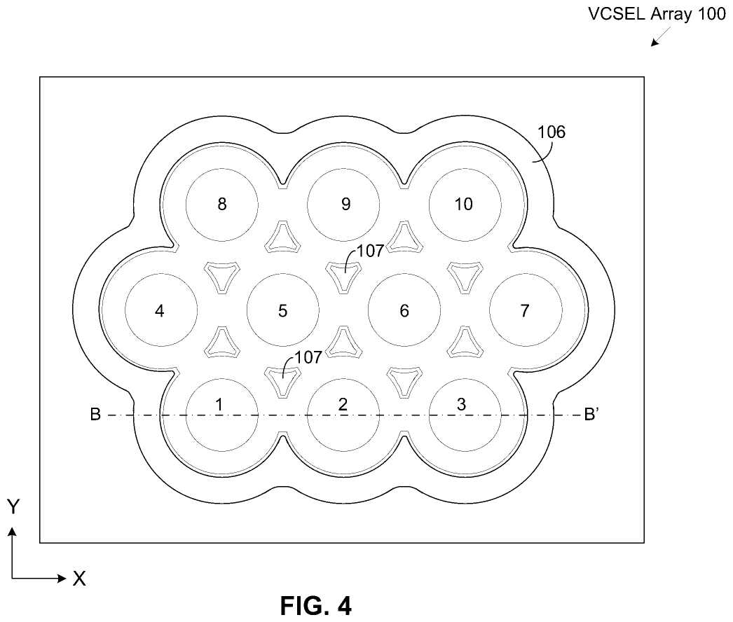

FIGS. 4 and 5 schematically show VCSEL array 100 in a top view and a cross-sectional view after a trench 106 and holes 107 are formed according to embodiments of the present invention. FIG. 5 is taken along a line BB′ of FIG. 4. After metal layer 110 is grown, a deposition process is performed to grow a dielectric layer 112 (e.g., a silicon nitride layer) over the top surface of array 100 by CVD or atomic layer deposition (ALD). Layer 112 covers metal layer 110 and certain other areas of array 100. In some aspects, layer 112 with optical thickness equal to multiples of half the lasing wavelength is used as a transparent passivation layer to protect metal layer 110 and reduce reflection of the top surface. In some other aspects, an additional dielectric layer (not shown) may be deposited over layer 112. In these cases, layer 112 and the additional dielectric layer form a transparent passivation layer together.

Trench 106 and holes 107 are configured for an oxidation process. Holes 107 may also be referred to as trenches in some aspects. The shape, quantity, dimension, and arrangement of trench 106 and holes 107 as illustrated in FIG. 4 and in other figures in the present disclosure are exemplary and for description purposes. The trench and holes may be made concurrently by a dry etch or a combination of dry and wet etch processes. In an X-Y plane or horizontal plane, trench 106 encircles the area of VCSEL elements 1-10, while holes 107 are around or surround areas where the VCSEL elements will be made. In addition, each of holes 107 is between or among areas where adjacent VCSEL elements will be made. Trench 106 also encircles holes 107 in the X-Y plane. Along the Z direction or vertical direction, the trench and holes may extend through the top reflector region 102 and active region 101 in some embodiments. Optionally, the trench and holes may extend through the top reflector region 102 and active region 101 and into the bottom reflector region 103. After trench 106 and holes 107 are formed, ends of the high Al-content layer 105 are exposed on the sidewalls.

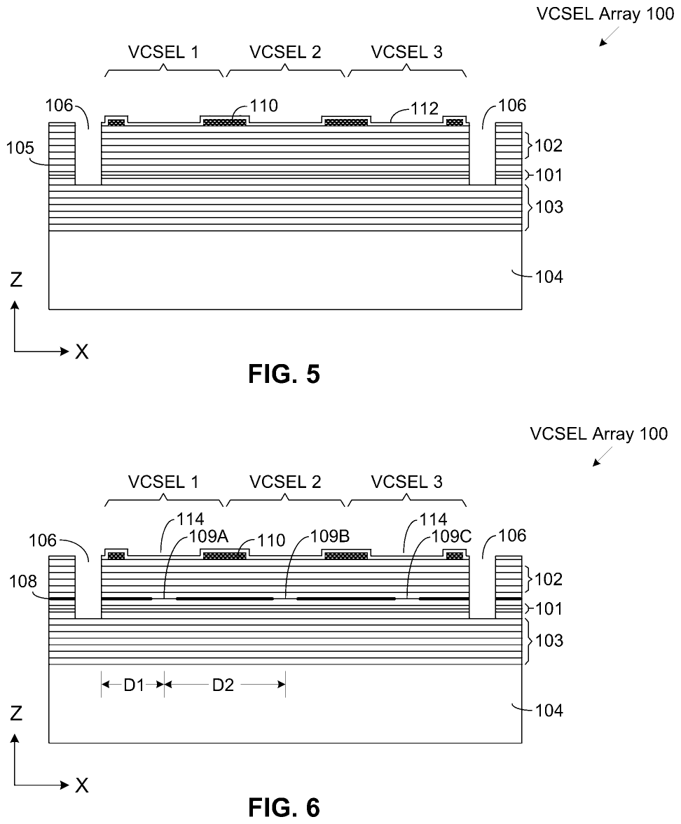

FIG. 6 schematically shows VCSEL array 100 at a fabrication stage after a timed oxidation process according to embodiments of the present invention. The oxidation process may be performed in a high temperature (e.g., 400 degrees Celsius) steam environment or a dry oxygen environment. Part of high Al-content layer 105 is converted into an oxide layer 108 (e.g., AlₓO_{y} layer) by the oxidation. The oxidation rate is strongly dependent on the Al content. For example, layer 105 may contain Al_{0.9}Ga_{0.1}As or AlAs. Certain parts of layer 105 that are not oxidized form oxide apertures with a circle-like shape, providing electrical and optical confinement for the VCSEL elements. Ten oxide apertures are made corresponding to VCSEL elements 1-10. FIG. 6 illustrates oxide apertures 109A, 109B, and 109C for VCSELs 1-3, respectively. FIG. 6 also shows output windows 114 within the metal layer rings. The oxide aperture, metal layer ring, and output window are concentric around a Z axis at a VCSEL element. As used herein the terms “VCSEL”, “VCSEL element”, and “VCSEL emitter” have the same meaning and indicate a VCSEL of array 100.

Assuming line BB′ of FIG. 4 goes through centers of the metal layer rings of VCSEL elements 1-3. As such, the cross-sectional view of FIG. 6 passes through centers of the metal layer rings of VCSEL elements 1-3 and centers of oxide apertures 109A-109C. As used herein, an inner edge of trench 106 indicates a sidewall of trench 106 that is also the edge or boundary of the area of VCSEL elements 1-10. Assuming the distance between the inner edge of trench 106 and the center of oxide aperture 109A is D1, and the distance between centers of adjacent oxide apertures (e.g., 109A and 109B) is D2. D2 is also the distance between centers of the adjacent metal layer rings of VCSEL elements 1 and 2. In some cases, D2 may be considered as the pitch of VCSEL array 100 in the X direction. Array 100 may be designed to utilize optimized small pitch to arrange more VCSEL elements. Further, an ion implantation region surrounding the array area for electrical isolation is not configured. In the present disclosure, trench 106 also functions as an isolation region for array 100. Without an ion implantation process, the cost of VCSEL array 100 may be reduced. As oxide aperture 109A is adjacent to trench 106, the center of oxide aperture 109A may be closer to trench 106 without an ion implantation region. In some aspects, the value of D1 may be in a range of 0.5D2 to D2. Optionally, the value of D1 may be smaller than 0.7D2 in some embodiments. As the output window and oxide aperture of a VCSEL are aligned along the Z direction, D1 is also the distance between the inner edge of trench 106 and the center of output window 114, and D2 is the distance between centers of the output windows of VCSEL elements 1 and 2.

Further, when the pitch of array 100 is minimized, the p-metal contacts or the metal layer rings of adjacent VCSEL elements become proximate. As illustrated above, adjacent VCSEL elements may share a part of the p-metal contact. The shared part of the metal layer, as shown in FIGS. 3 and 6, connects the metal layer rings of adjacent VCSEL elements. Further, as there is no ion implantation region surrounding VCSELs 1-10, the p-metal contacts of some VCSEL elements may be very close to trench 106.

In some cases, after the oxidation process, trench 106 and holes 107 are filled by one or more dielectric materials (e.g., silicon oxide or silicon nitride). Optionally, the trench and holes may be filled at another fabrication stage. In descriptions below, trench 106 and holes 107 remain open or partially filled for illustration purposes.

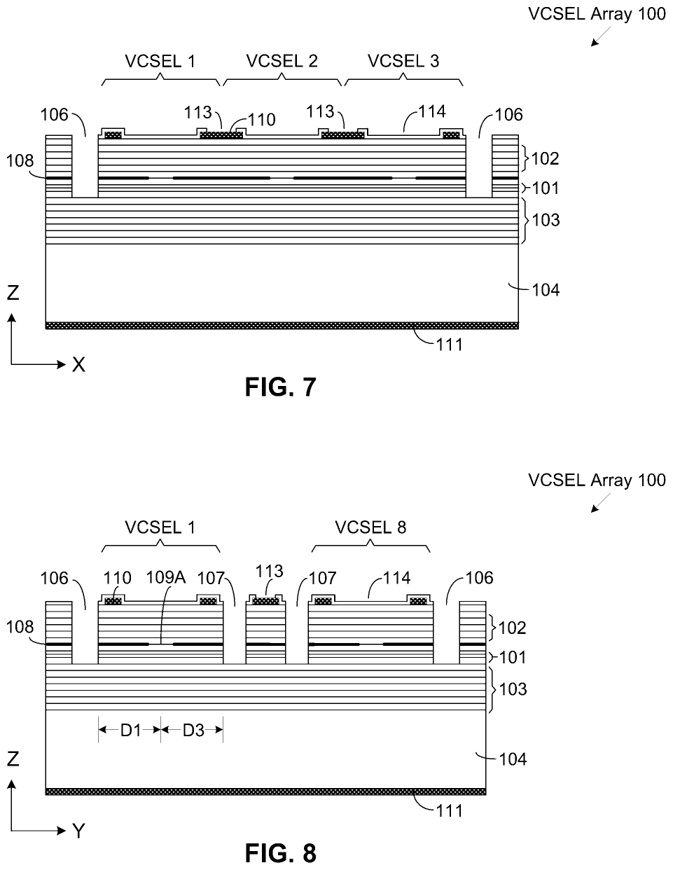

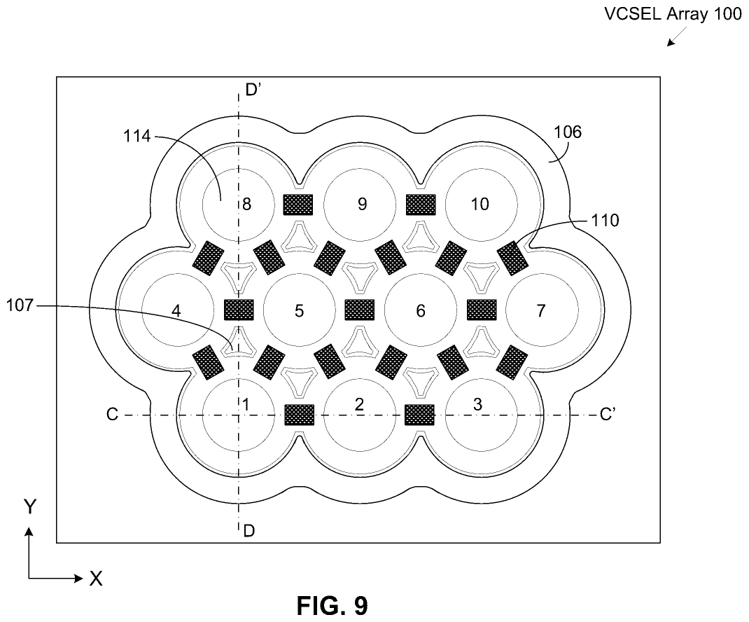

FIGS. 7, 8, and 9 schematically show VCSEL array 100 in cross-sectional and top views at a fabrication stage according to embodiments of the present invention. FIGS. 7 and 8 are taken along lines CC′ and DD' of FIG. 9, respectively. As shown in FIG. 9, trench 106 surrounds VCSEL elements 1-10, while holes 107 are between VCSEL elements 1-10. Further, holes 107 are around or surround each VCSEL element, respectively. After the oxidation process, a dry and/or wet etch is performed to remove certain sections of layer 112 that are over the shared parts of the metal layers of adjacent VCSEL elements. Openings 113 are formed. As shown in FIGS. 7 and 8, openings 113 are aligned to the shared parts of metal layers 110 in the Z direction, and expose the shared parts at the bottom. Opening 113 may also be referred to as a via or via structure. Optionally, some of openings 113 may also be aligned to parts of metal layers 110 that are not shared by adjacent VCSEL elements. The quantity, shape, dimension, and arrangement of openings 113 as illustrated in FIGS. 7-9 are exemplary and for description purposes.

In some cases, a pad metal layer (not shown) may be deposited over parts of metal layer 110 that are exposed in openings 113 by CVD. Optionally, a dielectric layer such as a silicon oxide layer may be grown over the pad metal layer and the output windows by CVD or ALD. The dielectric layer covering the pad metal layer may be removed by etch subsequently.

Referring to FIGS. 4, 8, and 9, each of holes 107 is between or among areas of adjacent VCSEL elements. As shown in FIG. 8, assuming D3 is the distance between an edge of hole 107 and the center of oxide aperture 109A (or the center of VCSEL 1's output window), wherein the edge is adjacent to and faces oxide aperture 109A. As used herein, an edge of a hole (e.g., hole 107) indicates a sidewall of the hole that is also the edge or boundary of a VCSEL element's area. In such cases, the value of D3 may be in a range of 0.5D2 to D2 as well.

Further, a metal layer 111 is deposited on the bottom surface of substrate 104 as shown in FIGS. 7-8. Metal layers 110 and 111 serve as the anode and cathode contacts of VCSEL array 100, respectively. Metal layers 110-111 and the pad metal layer may include a metallic material, such as gold, silver, aluminum, copper, or any combination thereof.

In some other embodiments, metal layer 110 may be deposited after the oxidation process is conducted. In these cases, bottom reflector region 103, active region 101, and top reflector region 102 are epitaxially grown. Further, trench 106 and holes 107 are etched, followed by an oxidation process. Oxide apertures are created. Thereafter, metal layer 110 is made with optional shapes of rings. Further, a deposition process is performed to cover the top surface including metal layer 110 with a dielectric layer. Openings are etched to expose certain portions of metal layer 110, and a pad metal layer is grown on the exposed portions subsequently. Further, metal layer 111 is deposited on the bottom surface of the substrate.

In some other cases, instead of etching trench 106, a mesa structure is formed. In such cases, VCSELS 1-10 may be fabricated at the mesa structure with methods the same as or similar to that described above. For example, the boundary line between the mesa structure and the space surrounding the mesa structure may be viewed as the inner boundary line of trench 106, i.e., the boundary line between trench 106 and the array region. The array region contains all VCSEL elements of the array. A VCSEL array made at the mesa structure may have the same features as or similar features to that of array 100.

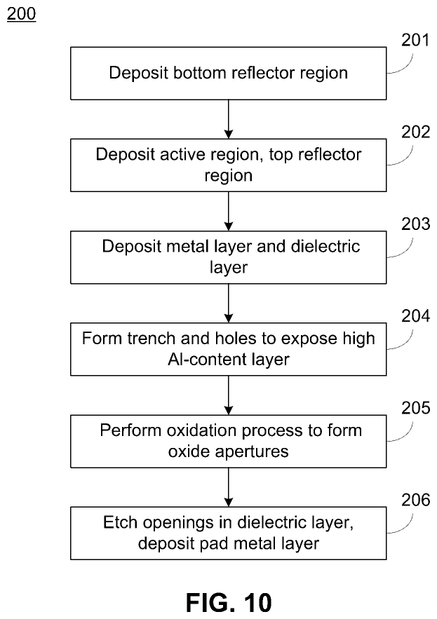

FIG. 10 is a flow chart illustrating a schematic fabrication process 200 for a VCSEL array, according to embodiments of the present invention. Process 200 starts from providing a semiconductor substrate such as a semiconductor wafer. At step 201, multiple layers as a bottom reflector region are grown epitaxially over the substrate. The bottom reflector region includes a DBR structure. At step 202, an active region is grown over the bottom reflector region epitaxially. The active region may include a quantum-well structure such as a MQW configuration. Further, multiple layers as a top reflector region are grown over the active region epitaxially. The top reflector region includes another DBR structure. In some aspects, a high Al-content layer is formed between the top reflector region and active region. The high Al-content layer contains relatively higher aluminum content than other epitaxial layers.

At step 203, a metal layer as the p-metal is deposited over the top reflector region. In some cases, the metal layer contains multiple ring shapes. Each ring encircles an output window of a VCSEL element. In some other cases, an output window may be surrounded by parts of the metal layer that are separate sections of a ring. In some aspects, each pair of adjacent VCSEL elements may share at least one section of the p-metal contact. In some other aspects, each pair of adjacent VCSEL elements must share at least one piece of p-metal contact. For example, the shared part may connect the ring-shaped contacts (or segments of the contacts) of adjacent VCSEL elements. The shared contacts can reduce the pitch of the VCSEL array while maintaining the same oxide aperture size in some cases.

Further, a dielectric layer such as a silicon nitride layer is deposited over the top surface of the VCSEL array. The dielectric layer covers the p-metal contacts, e.g., the metal layer rings. The dielectric layer also covers the output windows. In some embodiments, the dielectric layer is formed as a transparent layer for the output window.

At step 204, a trench and multiple holes are formed by etch. Ends of the high Al-content layer are exposed on the sidewalls. In a horizontal plane, the trench is arranged to surround and encircle the entire area of the VCSEL array. The holes are arranged to surround or be around each VCSEL element of the array individually. In a vertical direction, the trench and holes extend to the same depth or similar depths in some cases. The depth of the trench and holes is arranged to expose the high Al-content layer on the sidewall in some aspects. Optionally, the trench and holes may pass through the top reflector region and active region. In some other cases, the trench and holes may pass through the top reflector region and active region, and penetrate into the bottom reflector region.

At step 205, an oxidation process (e.g., using hot water vapor) is implemented to oxidize the exposed high Al-content layer via the trench and holes. An oxide layer and oxide apertures are formed by the oxidation process. The oxide apertures have a circle-like shape and are made for each VCSEL element. Because there is no ion implantation region surrounding the area of the VCSEL array, for an oxide aperture adjacent to the trench, the distance between the inner edge of the trench and the center of the oxide aperture may be larger than 50% of and smaller than the distance between centers of two adjacent oxide apertures (i.e., oxide apertures of adjacent VCSEL elements) in some embodiments.

The trench and holes may be filled with one or more dielectric materials to form an isolation region after the oxidation process. Alternatively, the trench and holes may be filled with dielectric materials at a later stage. Optionally, the trench and holes may be partially filled. Further, a bottom contact metal layer (i.e., the n-metal contact) is deposited.

At step 206, parts of the dielectric layer are etched selectively, making openings to expose certain sections of the p-metal contacts. Optionally, some openings are aligned to and expose the shared parts of the p-metal contacts between two adjacent VCSEL elements. Subsequently, pad metal layers are deposited over the exposed p-metal contacts.

Besides a single VCSEL array, the methods illustrated above may also be implemented to fabricate multiple VCSEL arrays on a chip concurrently. Since an ion implantation region is not arranged to encircle the area of the VCSEL array, a corresponding ion implantation process is not performed. Compared to methods that use an ion implantation process to make a surrounding isolation region, the manufacturing cost of VCSEL arrays may be reduced.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

We claim:

1. A Vertical Cavity Surface Emitting Laser (VCSEL) array, comprising:
a substrate;
a plurality of VCSEL elements including a first element and a second element over the substrate; and
a trench surrounding the plurality of VCSEL elements, wherein the first and second elements are adjacent, and the first element includes:
a first reflector region over the substrate;
a second reflector region over the first reflector region;
an active region between the first reflector region and second reflector region;
a part of a metal layer shared by the first and second elements; and
a first output window, a distance between an inner edge of the trench and a center of the first output window being larger than half a distance between the center of the first output window and a center of a second output window of the second element.

2. The VCSEL array of claim 1, wherein the first element further includes a first oxide aperture between the first reflector region and second reflector region, a distance between the inner edge of the trench and a center of the first oxide aperture is larger than fifty percent of a distance between the center of the first oxide aperture and a center of a second oxide aperture of the second element and smaller than the distance between the centers of the first and second oxide apertures.

3. The VCSEL array of claim 1, wherein the trench is filled with one or more dielectric materials.

4. The VCSEL array of claim 1 further comprising a plurality of holes around each of the plurality of VCSEL elements, wherein the trench and holes are arranged for performing an oxidation process to form oxide apertures.

5. The VCSEL array of claim 4, wherein the plurality of holes are filled with one or more dielectric materials.

6. The VCSEL array of claim 1, wherein the distance between the inner edge of the trench and the center of the first output window is smaller than the distance between the centers of the first and second output windows.

7. A Vertical Cavity Surface Emitting Laser (VCSEL) array, comprising:
a substrate;
a plurality of VCSEL elements including a first element and a second element over the substrate; and
a trench surrounding the plurality of VCSEL elements, wherein the first and second elements are adjacent, and the first element includes:
a first reflector region over the substrate;
a second reflector region over the first reflector region;
an active region between the first reflector region and second reflector region; and
a first oxide aperture between the first reflector region and second reflector region, a distance between an inner edge of the trench and a center of the first oxide aperture being larger than fifty percent of a distance between the center of the first oxide aperture and a center of a second oxide aperture of the second element and smaller than the distance between the centers of the first oxide aperture and the second oxide aperture.

8. The VCSEL array of claim 7, wherein the trench is filled with one or more dielectric materials.

9. The VCSEL array of claim 7 further comprising a plurality of holes around each of the plurality of VCSEL elements, wherein the trench and holes are arranged for performing an oxidation process.

10. The VCSEL array of claim 9, wherein the plurality of holes are filled with one or more dielectric materials.

11. The VCSEL array of claim 7, wherein the first element further includes a first output window, and a distance between the inner edge of the trench and a center of the first output window is larger than half a distance between the center of the first output window and a center of a second output window of the second element.

12. A method for fabricating a Vertical Cavity Surface Emitting Laser (VCSEL) device, comprising:
forming a plurality of VCSEL elements over a substrate;
forming a metal layer including a part shared by a first element and a second element of the plurality of VCSEL elements, the first and second element being adjacent;
forming a trench surrounding the plurality of VCSEL elements;
forming a plurality of holes around each of the plurality of VCSEL elements; and
forming a first output window and a second output window of the first and second elements, respectively, a distance between an inner edge of the trench and a center of the first output window being larger than fifty percent of a distance between the center of the first output window and a center of the second output window.

13. The method of claim 12 further comprising forming a first oxide aperture and a second oxide aperture of the first and second elements, respectively, wherein a distance between the inner edge of the trench and a center of the first oxide aperture is larger than fifty percent of a distance between the center of the first oxide aperture and a center of the second oxide aperture and smaller than the distance between the centers of the first and second oxide apertures.

14. The method of claim 12 further comprising filling the trench and the plurality of holes with one or more dielectric materials.

15. The method of claim 12 further comprising performing an oxidation process to form a plurality of oxide apertures for the plurality of VCSEL elements using the trench and the plurality of holes.

16. The method of claim 12, wherein a portion of the metal layer has a shape of a ring surrounding the first output window, and a distance between the inner edge of the trench and the ring is smaller than a difference between an outer radius and an inner radius of the ring.

17. The method of claim 12, wherein the distance between the inner edge of the trench and the center of the first output window is smaller than the distance between the centers of the first and second output windows.
